(19) United States
(12) Patent Application Publication
(10) Pub. No.: US 2013/0214649 A1
(43) Pub. Date: Aug. 22, 2013

(54) METHOD FOR FABRICATING PIEZOELECTRIC DEVICE AND PIEZOELECTRIC DEVICE

(71) Applicant: NIHON DEMPA KOGYO CO., LTD., (US)

(72) Inventors: SHUICHI MIZUSAWA, SAITAMA (JP); TAKEHIRO TAKAHASHI, SAITAMA (JP)

(73) Assignee: NIHON DEMPA KOGYO CO., LTD., TOKYO (JP)

(21) Appl. No.: 13/769,831

(22) Filed: Feb. 19, 2013

(30) Foreign Application Priority Data
Feb. 20, 2012 (JP) 2012-033925

(51) Int. Cl. H01L 41/047

(52) U.S. Cl. CPC H01L 41/047
USPC 310/366; 29/25.35

(57) ABSTRACT

A method for fabricating a piezoelectric device includes preparing a piezoelectric wafer, preparing a first wafer, bonding the piezoelectric wafer and the first wafer, preparing a first terminal mask for forming a pair of hot terminals on the bottom surface and a second terminal mask for forming the pair of hot terminals and a grounding terminal as a ground point, selecting an arrangement of the first terminal mask and an arrangement of the second terminal mask on a bottom surface of the first wafer after the wafer bonding, and forming a bottom surface with the power supply terminal and the output terminal through the first terminal mask, or a bottom surface with the power supply terminal, the output terminal, and the grounding terminal through the second terminal mask, after selecting the arrangement.

### CROSS REFERENCE TO RELATED APPLICATIONS

This application claims the priority benefit of Japan application serial no. 2012-033925, filed on Feb. 20, 2012. The entirety of the above-mentioned patent application is hereby incorporated by reference herein and made a part of this specification.

### TECHNICAL FIELD

This disclosure relates to a method for fabricating a piezoelectric device to be mounted on a printed circuit board and the piezoelectric device. Especially, this disclosure relates to a fabrication method for easily fabricating a piezoelectric device with varied mounting terminals.

### DESCRIPTION OF THE RELATED ART

Electrical equipment and similar equipment are desired to be downsized and/or lightweight. Additionally, a piezoelectric device used for the electrical equipment or similar equipment is also desired to be downsized and/or lightweight. Thus, nowadays, there are a lot of piezoelectric devices with a surface mount type structure. There are various foot patterns (terminal patterns) of the piezoelectric device depending on a performance or a function of the electrical equipment. For example, the piezoelectric device includes a base portion with a bottom surface on which various foot patterns are formed. The various foot patterns include a foot pattern that includes two mounting terminals (hot terminals) of a power supply terminal and an output terminal, a foot pattern that includes a grounding terminal in addition to the mounting terminals, or a similar foot pattern (see Japanese Unexamined Patent Application Publication No. 2011-045041).

However, if a base portion with various positions of the mounting terminals, a piezoelectric vibration element suitable for the base portion, and a similar member are designed in each case corresponding to positions (foot patterns) of the various mounting terminals, this increases cost. Additionally, fabrication control of these members also increases the cost. In view of this, even if the mounting terminals are disposed in various positions (foot patterns), it is preferred to employ a common base portion or a common crystal resonator as much as possible.

A need thus exists for a method for fabricating a piezoelectric device and the piezoelectric device which are not susceptible to the drawback mentioned above.

### SUMMARY

A method for fabricating a piezoelectric device according to a first aspect includes preparing a piezoelectric wafer that includes a plurality of piezoelectric vibration elements and preparing a first wafer. The piezoelectric vibration element includes a piezoelectric piece and an outer frame. The piezoelectric piece includes a pair of excitation electrodes. The outer frame surrounds the piezoelectric piece. The outer frame includes a pair of extraction electrodes. The extraction electrodes are extracted from the excitation electrodes. The first wafer is made of insulating material that includes a plurality of first container bodies and a plurality of through holes. The first container body includes a first bonding surface to be bonded to one principal surface of the piezoelectric vibration element and a bottom surface at an opposite side of the first bonding surface. The plurality of through holes are at a common side shared by the adjacent first container bodies. The through hole passes through the adjacent first container bodies from the first bonding surface to the bottom surface. The method further includes bonding the piezoelectric wafer and the first wafer, preparing a first terminal mask and a second terminal mask. The first terminal mask is for forming a pair of hot terminals on the bottom surface. The hot terminals include a power supply terminal and an output terminal for vibration frequency. The second terminal mask is for forming the pair of hot terminals and a grounding terminal as a ground point. Additionally, the method includes selecting an arrangement of the first terminal mask and an arrangement of the second terminal mask on the bottom surface of the first wafer after the wafer bonding, and forming a bottom surface with the power supply terminal and the output terminal through the first terminal mask, or a bottom surface with the power supply terminal, the output terminal, and the grounding terminal through the second terminal mask, after selecting the arrangement.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a first piezoelectric device 100;

FIG. 2 is a cross-sectional view taken along the line A-A of the first piezoelectric device 100;

FIG. 3 is an exploded perspective view of a second piezoelectric device 200;

FIG. 4 is an exploded perspective view of a third piezoelectric device 300;

FIG. 5 is a flowchart illustrating fabrication of the first piezoelectric device 100, the second piezoelectric device 200 and the third piezoelectric device 300;

FIG. 6 is a plan view of a quartz-crystal wafer 20W;

FIG. 7 is a plan view (of a bottom surface) of a first wafer 30W for the first piezoelectric device 100;

FIG. 8 is a plan view (of a bottom surface) of a first wafer 40W for the second piezoelectric device 200;

FIG. 9 is a plan view (of a bottom surface) of a first wafer 50W for the third piezoelectric device 300;

FIG. 10 is a plan view (for a mounting surface) of an A-terminal mask 30M;

FIG. 11 is a plan view (for a mounting surface) of a B-terminal mask 40M; and

FIG. 12 is a plan view (for a mounting surface) of a C-terminal mask 50M.

### DETAILED DESCRIPTION

In this description, a piezoelectric vibration element employs an AT-cut crystal resonator. That is, the AT-cut crystal resonator has a principal surface (in the Y-Z plane) that is tilted by 35° 15′ about the Y-axis of crystallographic axes (XYZ) in the direction from the Z-axis to the Y-axis around the X-axis. Accordingly, the new axes tilted with reference to the axis directions of the AT-cut crystal resonator are denoted as the Y′-axis and the Z′-axis. This disclosure defines the longitudinal direction of the piezoelectric vibration element as the X-axis direction, the height direction of the piezoelectric vibration element as the Y′-axis direction, and the direction perpendicular to the X and Y′-axis directions as the Z′-axis direction.

### Overall Configuration of a First Piezoelectric Device 100

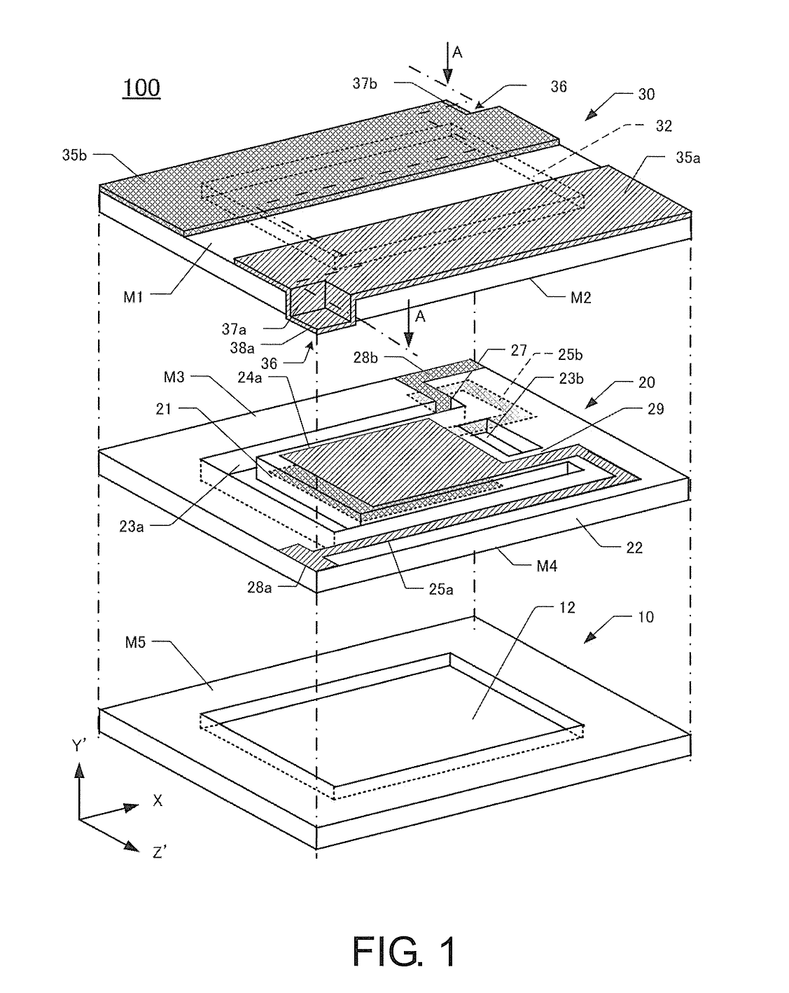

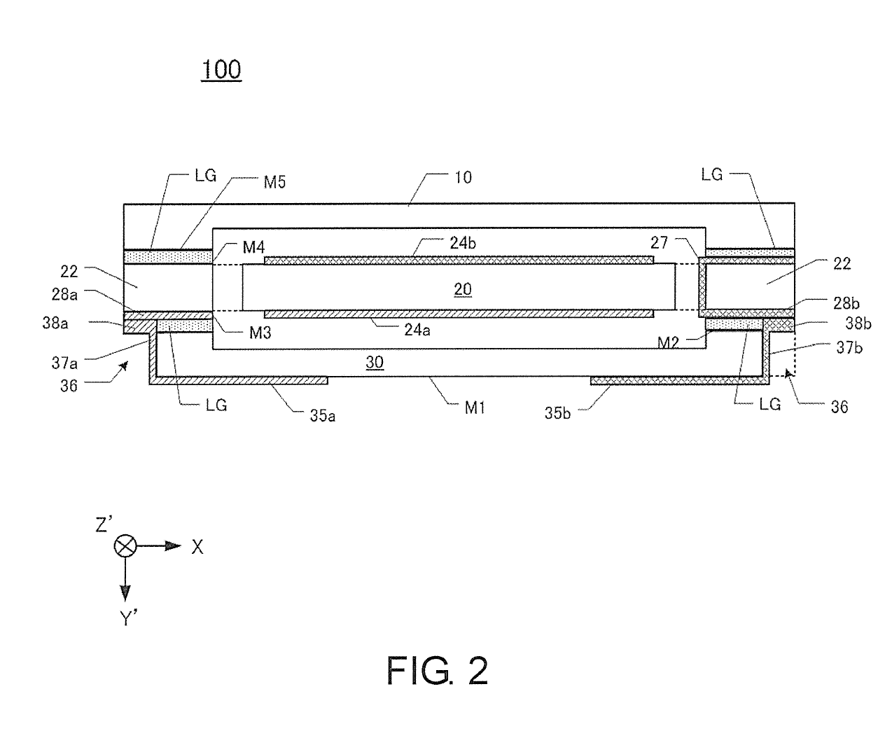

A description will be given of an overall configuration of a first piezoelectric device 100 by referring to FIG. 1 and FIG. 2. FIG. 1 illustrates a mounting surface in an exploded perspective view viewed from a first container body 30 side of the first piezoelectric device 100. FIG. 1 does not illustrate a sealing material LG. FIG. 2 is a cross-sectional view taken along the line A-A of FIG. 1.

As illustrated in FIG. 1 and FIG. 2, the first piezoelectric device 100 includes a second container body 10 with a depressed portion 12, a first container body 30 with a depressed portion 32, and a crystal resonator 20 with an outer frame 22.

The crystal resonator 20 is formed of an AT-cut quartz-crystal material. The crystal resonator 20 includes a quartz-crystal bonding surface M3 at the +Y′ side and a quartz-crystal bonding surface M4 at the −Y′ side. The crystal resonator 20 includes a quartz-crystal vibrating portion 21 and the outer frame 22, which surrounds the quartz-crystal vibrating portion 21. The quartz-crystal vibrating portion 21 has a rectangular shape. The outer frame 22 with four sides is a frame also in a rectangular shape. A U-shaped void 23a and a straight void 23b pass through in the vertical direction, and are formed between the quartz-crystal vibrating portion 21 and the outer frame 22. A pair of connecting portions 29 for the quartz-crystal vibrating portion 21 and the outer frame 22 is a portion where the void 23a and the void 23b are not formed. Only one connecting portion 29 may be formed instead of the pair of connecting portions 29. The quartz-crystal vibrating portion 21 may employ a mesa shape, which is thick in the Y′ axis direction.

An excitation electrode 24a and an excitation electrode 24b are respectively formed on the quartz-crystal bonding surface M3 and the quartz-crystal bonding surface M4 of the quartz-crystal vibrating portion 21. The excitation electrodes 24a and 24b are conductively connected to extraction electrodes 25a and 25b, which are formed on respective both surfaces of the outer frame 22. The extraction electrode 25a connects to a connecting electrode 28a. Additionally, a side surface electrode 27 is formed at the −Z′ side of the +X end in the void 23a. The extraction electrode 25b connects to the connecting electrode 28b via the side surface electrode 27.

Here, the excitation electrodes 24a and 24b, the extraction electrodes 25a and 25b, and the connecting electrodes 28a and 28b each employ, for example, a chromium layer as a foundation layer, and employ a gold layer on a surface of the chromium layer. The chromium layer has a thickness of, for example, 0.05 μm to 0.1 μM while the gold layer has a thickness of, for example, 0.2 μm to 2 μm.

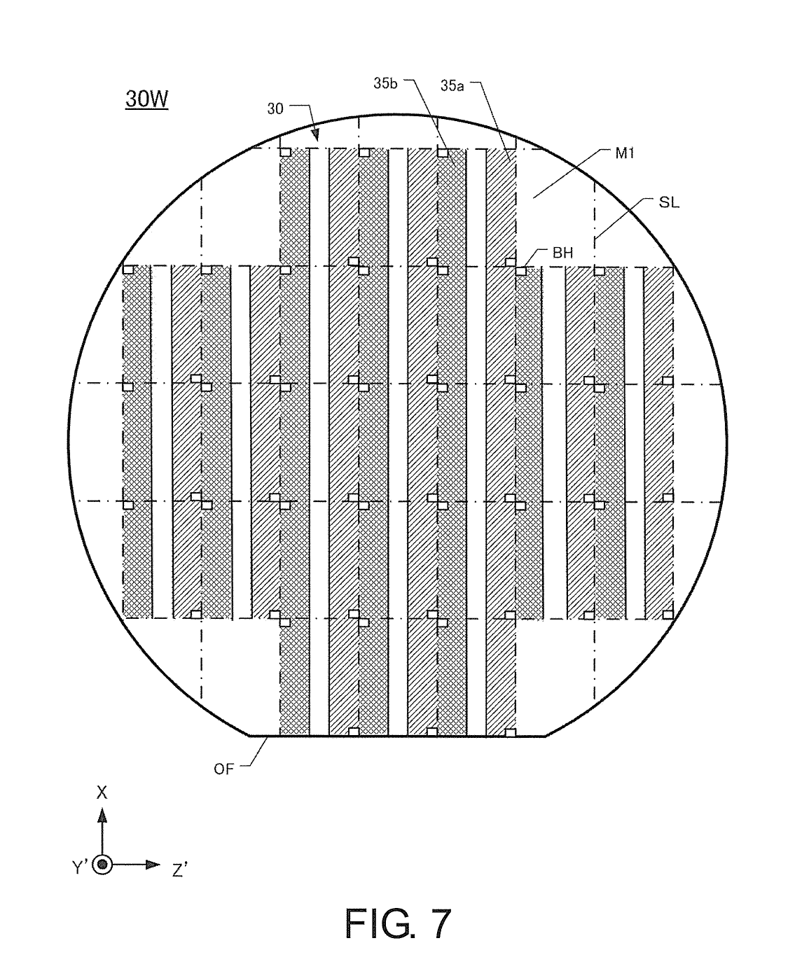

The first container body 30 is formed of glass or quartz-crystal material in a flat rectangular shape. The first container body 30 includes a bonding surface M2 and a mounting surface M1. The bonding surface M2 surrounds the depressed portion 32 formed on a surface at the −Y′ side. The mounting surface M1 is formed at the +Y′ side. Additionally, the first container body 30 includes a pair of electrode extraction portions 36 on both ends in the Z′-axis direction and in a diagonal line direction. The electrode extraction portion 36 is a part of a through hole BH (see FIG. 7).

As illustrated in FIG. 1, a pair of connecting electrodes 38a and 38b is formed at the bonding surface M2 side of the first container body 30. Here, the connecting electrode 38a electrically connects to a side surface electrode 37a. The connecting electrode 38b electrically connects to the side surface electrode 37b, which is disposed in a diagonal line direction of the first container body 30 with respect to the side surface electrode 37a. As illustrated in FIG. 2, the side surface electrodes 37a and 37b are each formed to cover a side surface of the sealing material LG.

Additionally, the first container body 30 includes, on the mounting surface M1, a pair of mounting terminals (hot terminals) 35a and 35b, which electrically connects to the respective side surface electrodes 37a and 37b. The mounting terminals 35a and 35b extend in the longitudinal direction (the X-axis direction) of the first container body 30. The mounting terminals 35a and 35b are arranged at both of the +Z′-axis side and the −Z′-axis side. The mounting terminals 35a and 35b connect to the respective connecting electrodes 38a and 38b via the side surface electrodes 37a and 37b. By sputtering, electroless plating, or similar method, the mounting terminals (the hot terminals) 35a and 35b, the side surface electrodes 37a and 37b, and the connecting electrodes 38a and 38b are concurrently formed.

The second container body 10 is formed of glass or quartz-crystal material in a flat rectangular shape. The second container body 10 includes the depressed portion 12 in a rectangular shape and a bonding surface M5, which surrounds the depressed portion 12.

As illustrated in FIG. 2, the bonding surface M2 of the first container body 30 is bonded to the quartz-crystal bonding surface M3 of the outer frame 22. This bonding conductively connects the mounting terminals (the hot terminals) 35a and 35b to the excitation electrodes 24a and 24b. Applying an alternating voltage (an electric potential that alternates between positive and negative polarities) to the mounting terminals (the hot terminals) 35a and 35b makes the crystal resonator 20 to produce a thickness-shear vibration. The bonding surface M5 of the second container body 10 is bonded to the quartz-crystal bonding surface M4 of the outer frame 22 in the crystal resonator 20.

As illustrated in FIG. 2, the bonding surface M5 of the second container body 10, the quartz-crystal bonding surfaces M3 and M4 of the crystal resonator 20, the bonding surface M2 of the first container body 30 are bonded with, for example, non-electrically conductive adhesive of the sealing material LG. The sealing material LG employs low-melting-point glass, polyimide resin, or epoxy resin. These sealing materials LG are excellent in resistant to water and humidity, and prevents vapor in the air from entering the cavity and also prevents degradation of vacuum in the cavity. The low-melting-point glass is formulated as a paste mixed with binder and solvent, and bonds the bonding surfaces M2 to M5 by calcining and cooling.

### Overall Configuration of a Second Piezoelectric Device 200

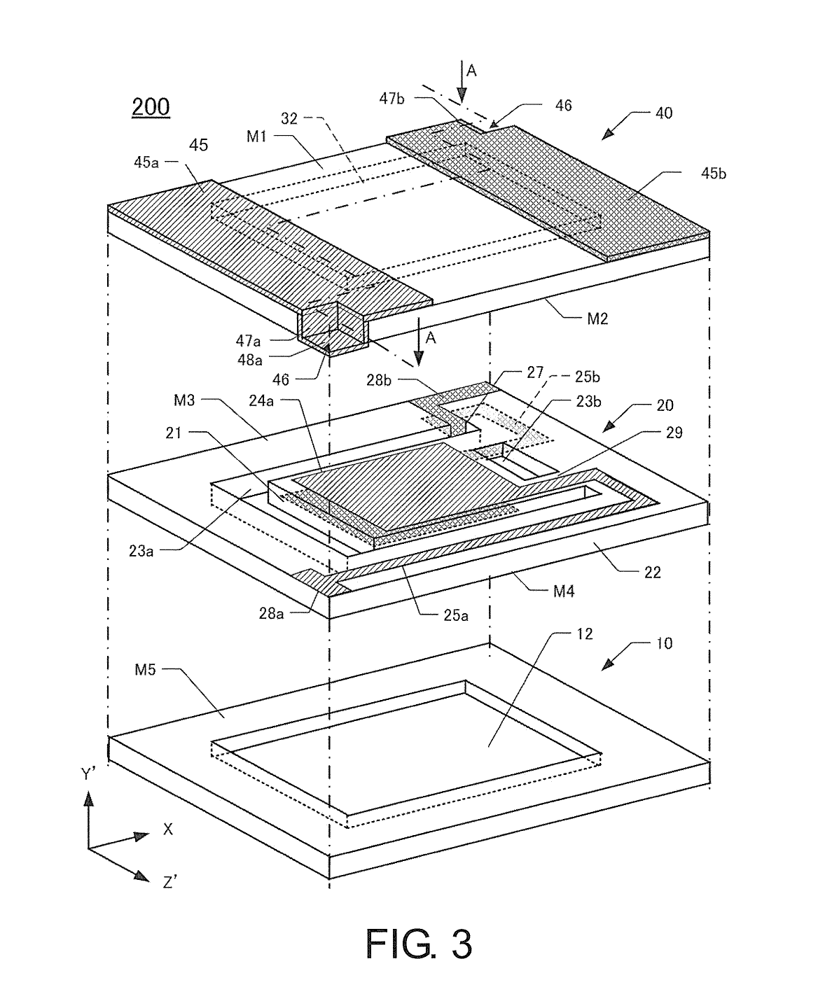

FIG. 3 is an exploded perspective view of a second piezoelectric device 200 viewed from a third container body 40 side. The second piezoelectric device 200 includes the second container body 10 with the depressed portion 12, the third container body 40 with the depressed portion 32, and the crystal resonator 20 with the outer frame 22.

The second piezoelectric device 200 differs from the first piezoelectric device 100 in that the third container body 40 includes mounting terminals 45a and 45b in a different shape. The shape of the mounting terminal is selected depending on a wiring pattern on the printed circuit board. Like reference numerals designate corresponding or identical elements to those of the first piezoelectric device 100. Therefore such elements will not be further elaborated here.

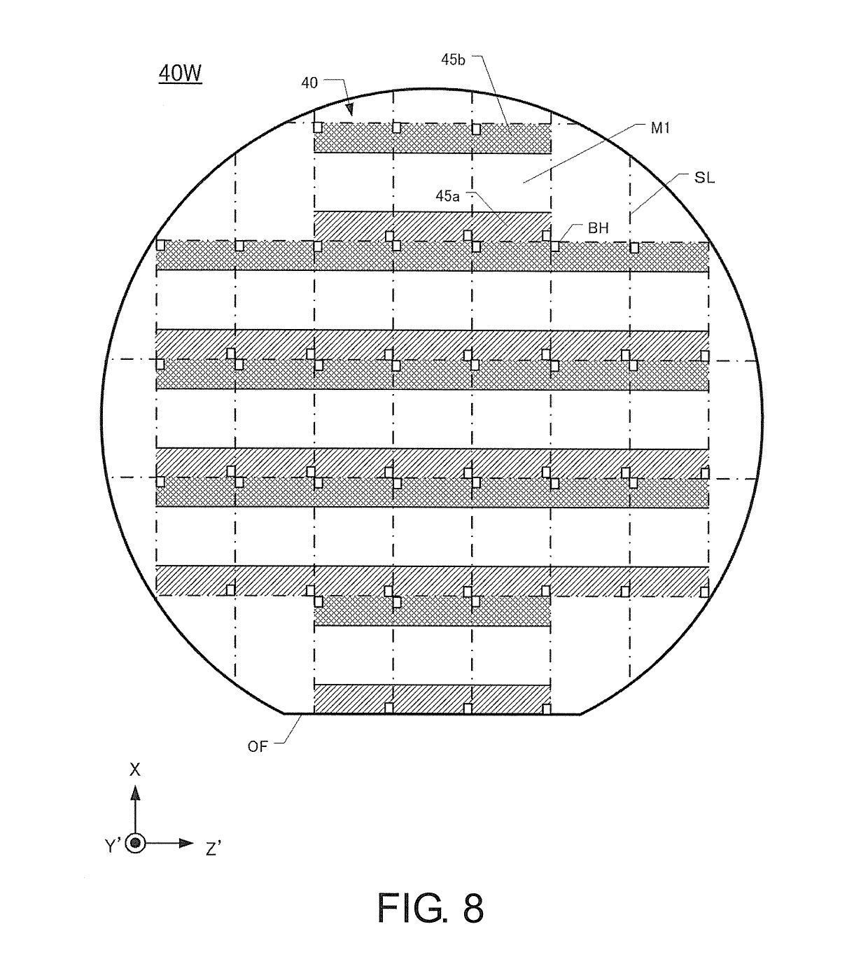

The third container body 40 includes the mounting surface M1 and the bonding surface M2. The mounting surface M1 of the third container body 40 includes mounting terminals 45a and 45b different from the mounting terminals (the hot terminals) 35a and 35b formed at the first container body 30 in the X-axis direction. The third container body 40 includes, on the mounting surface M1, a pair of mounting terminals (the hot terminals) 45a and 45b, which electrically connects to respective side surface electrodes 47a and 47b. The mounting terminals 45a and 45b extend in a short side direction (the Z′-axis direction) of the third container body 40. The mounting terminals 45a and 45b are respectively arranged at the −X-axis side and the +X-axis side. One of a pair of electrode extraction portions 46 includes the side surface electrode 47a connected to the mounting terminal 45a. Also, the side surface electrode 47a connects to a connecting electrode 48a. The other of the pair of electrode extraction portions 46 includes a side surface electrode 47b connected to the mounting terminal 45b. Also, the side surface electrode 47b connects to a connecting electrode 48b (not shown). The electrode extraction portion 46 is a part of a through hole BH (see FIG. 8).

### Overall Configuration of a Third Piezoelectric Device 300

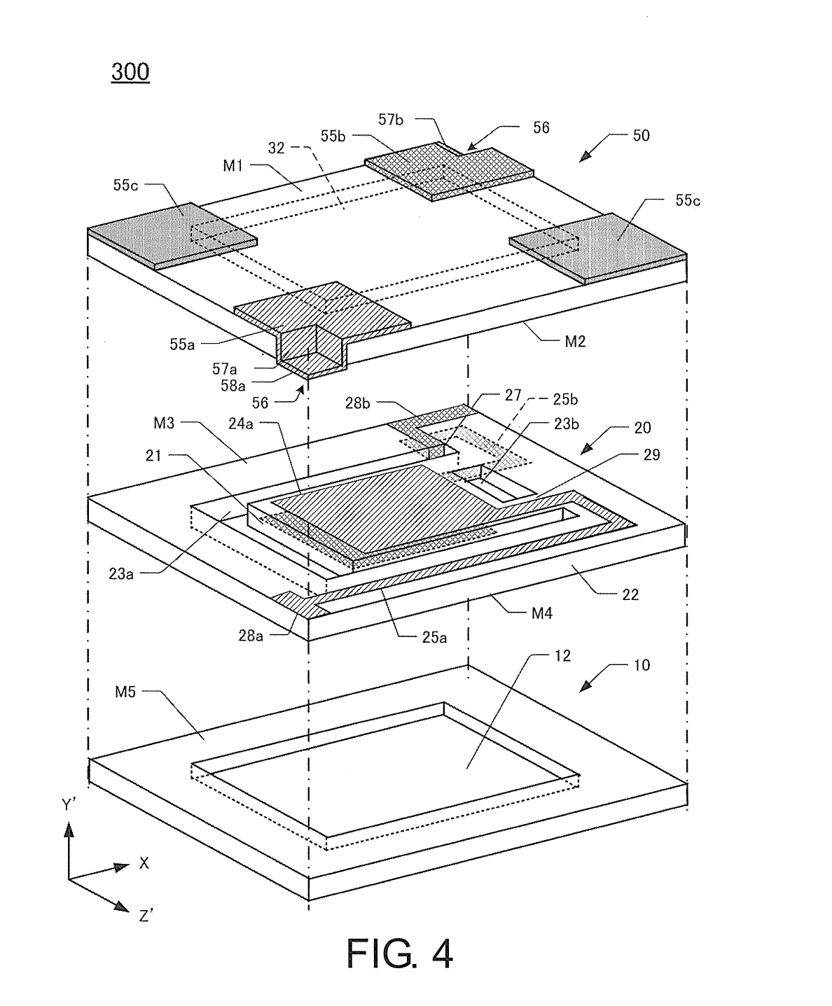

FIG. 4 is an exploded perspective view of a third piezoelectric device 300 viewed from a fourth container body 50 side. The third piezoelectric device 300 includes the second container body 10 with the depressed portion 12, the fourth container body 50 with the depressed portion 32, and the crystal resonator 20 with the outer frame 22.

The third piezoelectric device 300 differs from the first piezoelectric device 100 in that the fourth container body 50 includes mounting terminals 55a and 55b in a different shape. Like reference numerals designate corresponding or identical elements to those of the first piezoelectric device 100. Therefore such elements will not be further elaborated here.

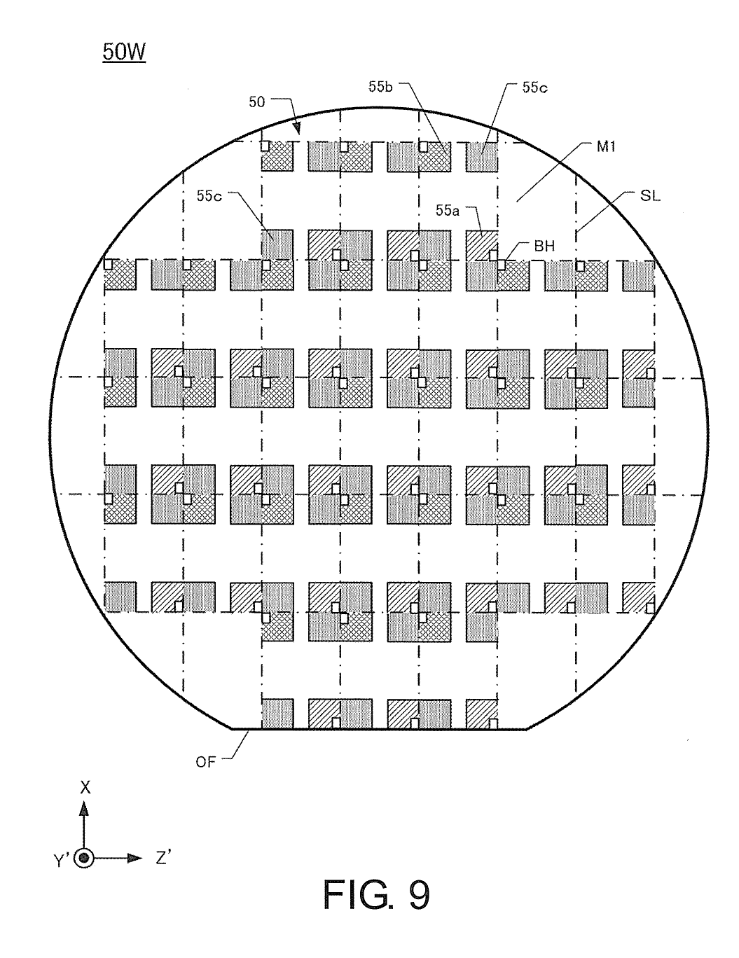

The fourth container body 50 includes the mounting surface M1 and the bonding surface M2. The mounting surface M1 of the fourth container body 50 includes four mounting terminals 55a to 55c. The fourth container body 50 includes a pair of electrode extraction portions 56 formed on respective ends in the Z′-axis direction and in a diagonal line direction. One of the pair of electrode extraction portions 56 includes a side surface electrode 57a connected to the mounting terminal 55a. Also, the side surface electrode 57a connects to a connecting electrode 58a. The other of the pair of electrode extraction portions 56 includes a side surface electrode 57b connected to the mounting terminal 55b. Also, the side surface electrode 57b connects to a connecting electrode 58b (not shown). The electrode extraction portion 56 is a part of a through hole BH (see FIG. 9).

The mounting terminals (the hot terminals) 55a and 55b among the four mounting terminals 55a to 55c are conductively connected to the excitation electrodes 24a and 24b. Applying an alternating voltage to the mounting terminals (the hot terminals) 55a and 55b makes the crystal resonator 20 to produce a thickness-shear vibration.

On the other hand, a pair of the mounting terminals 55c among the four mounting terminals 55a to 55c are mounting terminals for grounding terminals. That is, the mounting terminals (the grounding terminal) 55c are arranged in a diagonal line direction, which is different from that of the mounting terminals 55a and 55b of the fourth container body 50. Here, although the mounting terminals (the grounding terminal) 55c may be used as ground points, the mounting terminals (the grounding terminal) 55c may be used for strongly bonding the third piezoelectric device 300 to a printed circuit board for mounting (not shown). The mounting terminals 55c may not be electrically connected to a ground point of the printed circuit board.

### Method for Fabricating the First Piezoelectric Device 100, the Second Piezoelectric Device 200, and the Third Piezoelectric Device 300

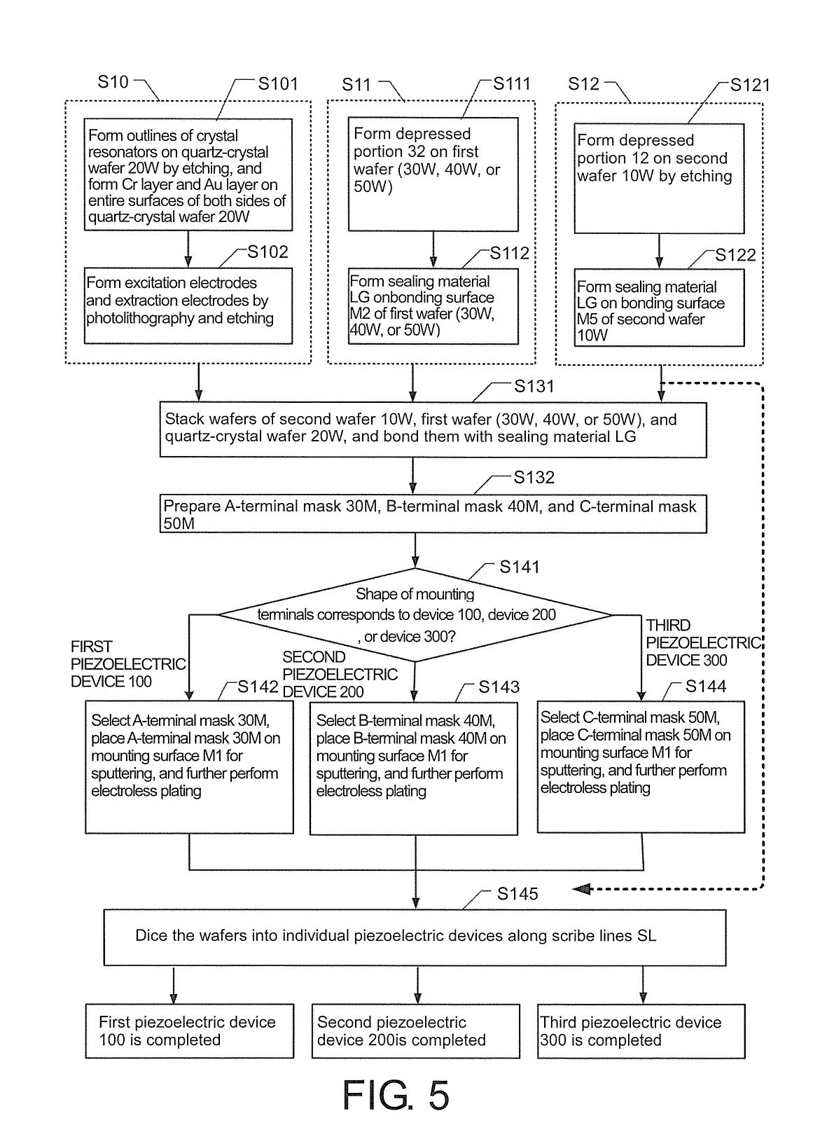

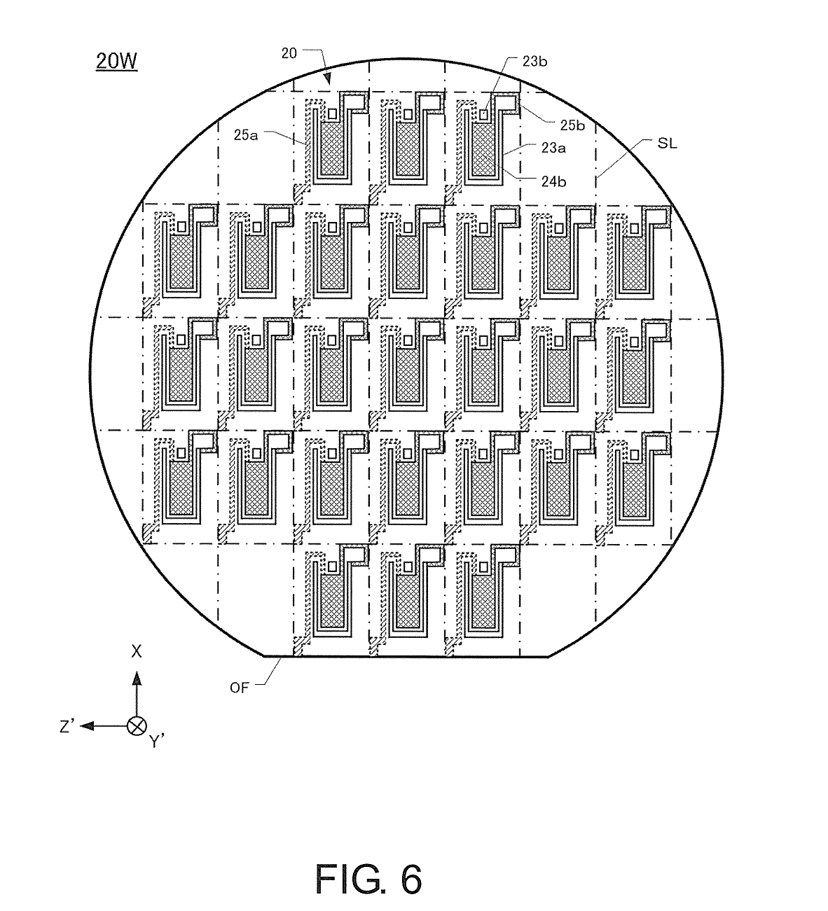

FIG. 5 is a flowchart illustrating fabrication of the first piezoelectric device 100, the second piezoelectric device 200, and the third piezoelectric device 300. FIG. 6 is a plan view of a quartz-crystal wafer 20W.

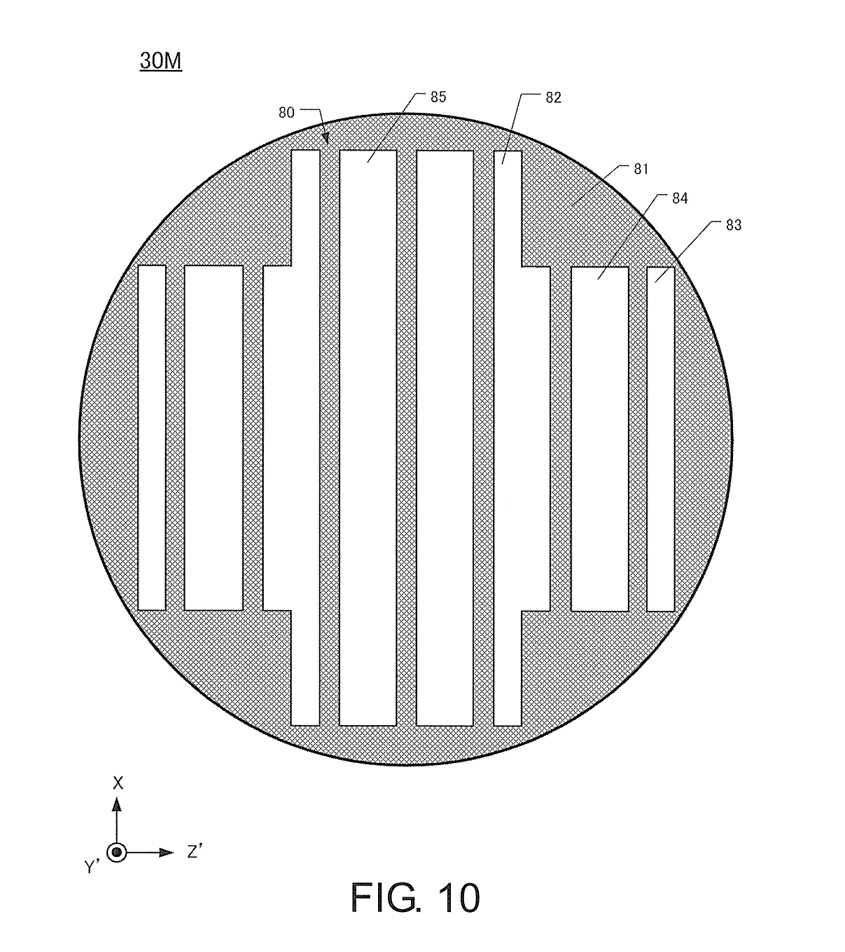

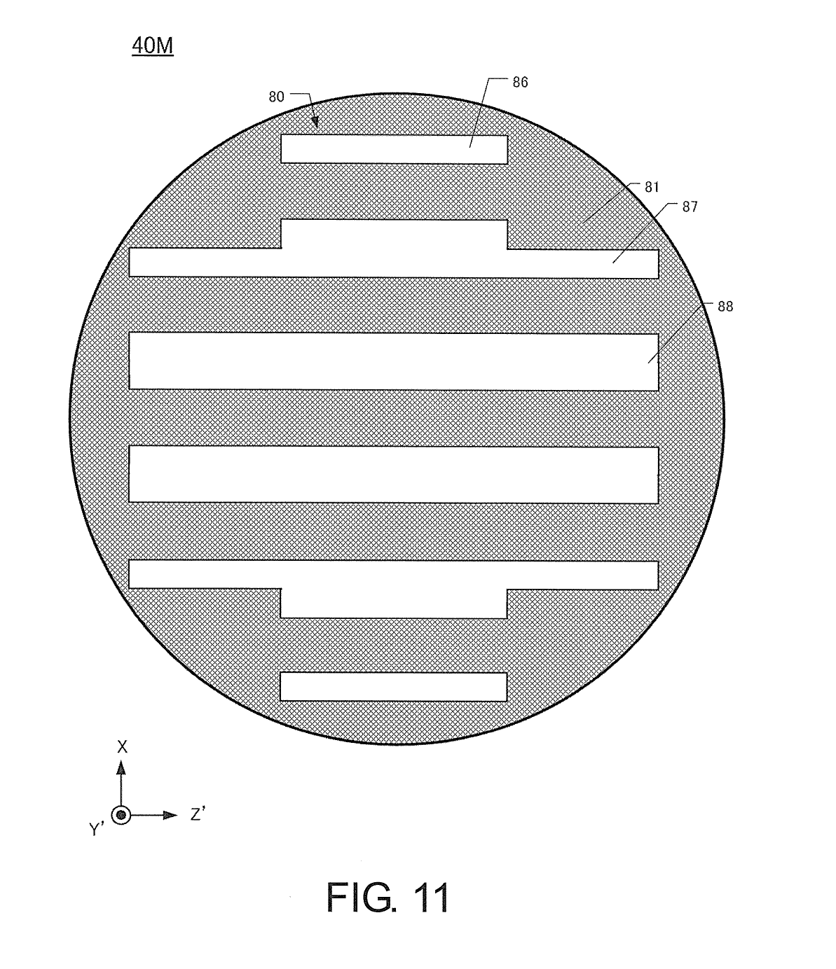

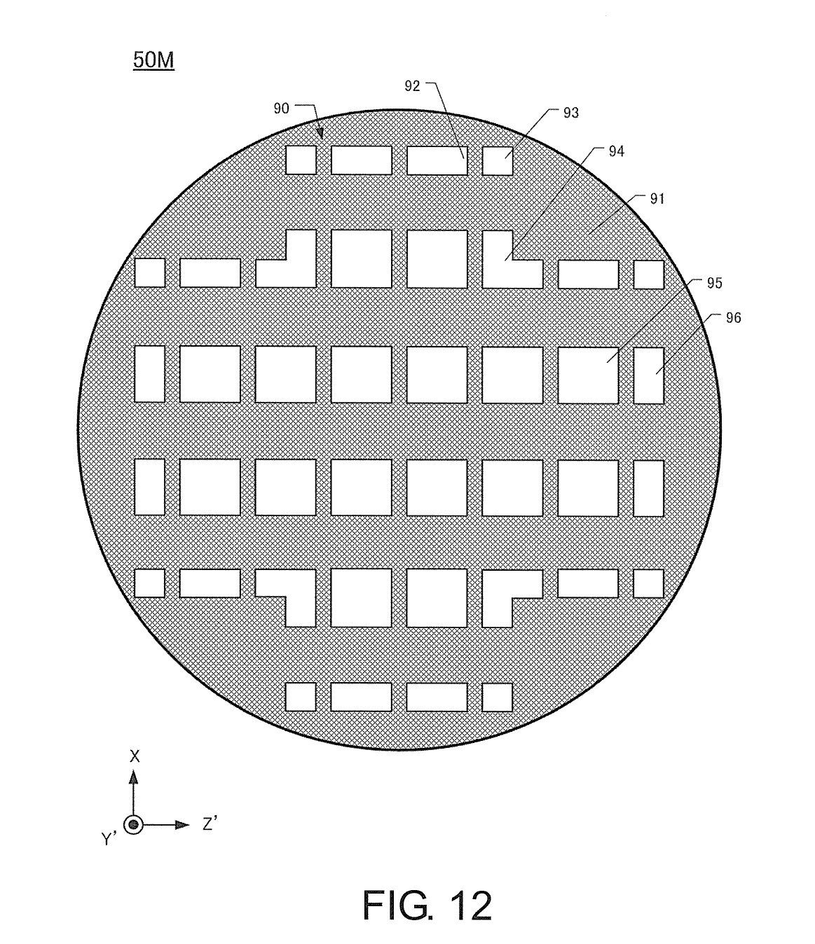

FIG. 7 is a plan view of a first wafer 30W fabricated for the first piezoelectric device 100. FIG. 8 is a plan view of a first wafer 40W fabricated for the second piezoelectric device 200. FIG. 9 is a plan view of a first wafer 50W fabricated for the third piezoelectric device 300. FIG. 7, FIG. 8, and FIG. 9 illustrate states where respective steps S142 to S144 of FIG. 5 are completed. FIG. 7, FIG. 8, and FIG. 9 illustrate the mounting terminals in mutually different positions (foot patterns). FIG. 10 is a plan view of an A-terminal mask 30M. FIG. 11 is a plan view of a B-terminal mask 40M. FIG. 12 is a plan view of a C-terminal mask 50M.

In step S10, the crystal resonator 20 is fabricated. Step S10 includes step S101 and step S102. In step S101, by wet etching, outlines of a plurality of crystal resonators 20 are formed on the quartz-crystal wafer 20W (see FIG. 6). That is, the quartz-crystal vibrating portion 21, the outer frame 22, and the voids 23a and 23b are formed on the quartz-crystal wafer 20W. Subsequently, by sputtering or vacuum evaporation, a chromium layer and a gold layer are formed in this order on both surfaces and a side surface of the quartz-crystal wafer 20W.

In step S102, photoresist is uniformly applied over the entire surface of the metal layer. Exposure equipment (not shown) exposes the quartz-crystal wafer 20W through a photomask with patterns of the excitation electrodes 24a and 24b, the extraction electrodes 25a and 25b, the side surface electrode 27, and the connecting electrodes 28a and 28b. Subsequently, the metal layer exposed through the photoresist is etched. As illustrated in FIG. 1 and FIG. 2, the quartz-crystal wafer 20W has both surfaces where the excitation electrodes 24a and 24b and the extraction electrodes 25a and 25b are formed.

In step S11, the first container body 30 is fabricated. Step S11 includes steps S111 and S112. In step S111, the first wafer 30W (or alternatively to be formed as 40W or 50W in a latter step) is prepared. Subsequently, by etching, the depressed portion 32 is formed on the bonding surface M2. The through hole BH (see FIG. 7 to FIG. 9), which passes through the first wafer 30W (or alternatively to be formed as 40W or 50W in a latter step), is formed in a portion corresponding to the two corners of the first container body 30 (or alternatively to be formed as the third container body 40 or the fourth container body 50 in a latter step). The through hole BH forms the electrode extraction portion 36, 46, or 56 (see FIG. 1, FIG. 3, or FIG. 4) after the first wafer 30W (or alternatively to be formed as 40W or 50W in a latter step) is divided into piezoelectric devices. This first wafer 30W (or alternatively to be formed as 40W or 50W in a latter step) has not included the mounting terminals yet. The first wafer 30W (or formed as 40W or 50W) is formed to have varied mounting terminals in each of steps S142 to S144. Before steps S142 to S144, the quartz-crystal wafers have the same shape with a through hole BH.

In step S112, the sealing material LG is uniformly formed on the bonding surface M2 (see FIG. 1 or FIG. 3), which is the peripheral portion of the depressed portion 32 in the first container body 30 (or alternatively to be formed as the third container body 40 or the fourth container body 50 in a latter step). For example, in the case where the sealing material LG is made of low-melting-point glass, this low-melting-point glass is applied over the bonding surface M2 by screen-printing and then temporarily calcined. In the case where the sealing material LG is polyimide resin, this polyimide resin is applied over the bonding surface M2 by screen-printing and then temporarily hardened. Instead of applying the low-melting-point glass or the polyimide resin over the bonding surface M2 of the first container body 30 (or alternatively to be formed as the third container body 40 or the fourth container body 50 in a latter step), the low-melting-point glass or the polyimide resin may be applied over the quartz-crystal bonding surface M3 of the outer frame 22.

In step S12, the second container body 10 is fabricated. Step S12 includes steps S121 and S122. In step S121, a second wafer 10W (not shown) is prepared. Subsequently, by etching, the depressed portion 12 (see FIG. 1 or FIG. 3) is formed on the second wafer 10W.

In step S122, the sealing material LG is uniformly formed on the bonding surface M5 (see FIG. 1), which is the peripheral portion of the depressed portion 12 in the second container body 10. For example, in the case where the sealing material LG is low-melting-point glass, this low-melting-point glass is applied over the bonding surface M5 by screen-printing and then temporarily calcined. In the case where the sealing material LG is polyimide resin, this polyimide resin is applied over the bonding surface M5 by screen-printing and then temporarily hardened. Instead of applying the low-melting-point glass or the polyimide resin over the bonding surface M5 of the second container body 10, the low-melting-point glass or the polyimide resin may be applied over the quartz-crystal bonding surface M4 of the outer frame 22.

In the flowchart of FIG. 5, step S10 for fabricating the crystal resonator 20, step S11 for fabricating the first container body 30 (or alternatively to be formed as the third container body 40 or the fourth container body 50 in a latter step), and step S12 for fabricating the second container body 10 can be performed separately and concurrently.

Subsequently, in step S131, the second wafer 10W, the first wafer 30W, and the quartz-crystal wafer 20W are bonded. The second wafer 10W, the first wafer 30W, and the quartz-crystal wafer 20W each have a part of a peripheral edge where an orientation flat OF (see FIG. 6 to FIG. 9) is formed. The second wafer 10W, the first wafer 30W, and the quartz-crystal wafer 20W are precisely stacked using the orientation flats OF as references. In the case where the sealing material LG is made of low-melting-point glass, the second wafer 10W, the first wafer 30W, and the quartz-crystal wafer 20W in the stack are placed in a chamber (not shown) filled with inert gas or a vacuum chamber (not shown), and heated to approximately 350° C. to 400° C. Then, the sealing material LG is melted, and the three wafers are pressed together. Subsequently, the sealing material LG is cooled to a room temperature to bond the three wafers. The stacked wafers have the cavity, which is filled with inert gas or evacuated to a vacuum level.

This process bonds the second wafer 10W, the first wafer 30W, and the quartz-crystal wafer 20W. Observation of the three wafers, which are bonded, from the first wafer 30W side allows viewing the connecting electrode 28a or 28b of the quartz-crystal vibrating portion 21 through the through hole BH. The first wafer 30W has not included the mounting terminals yet.

In step S132, for sputtering or vacuum evaporation, the A-terminal mask 30M (see FIG. 10), the B-terminal mask 40M (see FIG. 11), and the C-terminal mask 50M (see FIG. 12) are prepared.

The A-terminal mask 30M is a mask frame 80 made of metal, and includes a masked area 81 and foot pattern areas 82 to 85. The masked area 81 blocks metal particles caused by sputtering and a similar method. The foot pattern areas 82 to 85 have openings that allow the metal particles to pass through. The foot pattern areas 82 to 85 are formed longer in the X-axis direction (see FIG. 10). The foot pattern areas 82 to 85 are areas corresponding to the mounting terminals (the hot terminals) 35a and 35b, the side surface electrodes 37a and 37b, and the connecting electrodes 38a and 38b of the adjacent first container bodies 30.

The B-terminal mask 40M is the mask frame 80 made of metal, and includes the masked area 81 and foot pattern areas 86 to 88. The masked area 81 blocks metal particles caused by sputtering and a similar method. The foot pattern areas 86 to 88 have openings that allow the metal particles to pass through. The foot pattern areas 86 to 88 are formed longer in the Z-axis direction (see FIG. 11). The foot pattern areas 86 to 88 are areas corresponding to the mounting terminals (the hot terminals) 45a and 45b, the side surface electrodes 47a and 47b, and the connecting electrodes 48a and 48b of the adjacent third container bodies 40.

The C-terminal mask 50M is a mask frame 90 made of metal, and includes a masked area 91 and foot pattern areas 92 to 96. The masked area 91 blocks metal particles caused by sputtering and a similar method. The foot pattern areas 92 to 96 (see FIG. 12) have openings that allow the metal particles to pass through. The foot pattern areas 92 to 96 are areas corresponding to the mounting terminals (the hot terminals) 55a and 55b, the mounting terminals (the grounding terminals) 55c, the side surface electrodes 57a and 57b, the connecting electrodes 58a and 58b of the adjacent fourth container bodies 50. The foot pattern areas 92 to 96 corresponds to the mounting terminals (55a, 55b, 55c and, 55c) of the four adjacent fourth container bodies 50, and are in square shapes.

Subsequently, in step S141, fabrication of the first piezoelectric device 100, fabrication of the second piezoelectric device 200, or fabrication of the third piezoelectric device 300 is selected. When fabricating the first piezoelectric device 100, the process proceeds to step S142. When fabricating the second piezoelectric device 200, the process proceeds to step S143. When fabricating the third piezoelectric device 300, the process proceeds to step S144. The piezoelectric devices 100 to 300 are selected by a specification and similar criterion by a client in step S141.

In step S142, a mounting terminal pattern for the first piezoelectric device 100 is fabricated. The A-terminal mask 30M with the patterns of the mounting terminals 35a and 35b is selected. The A-terminal mask 30M is placed on the mounting surface M1 of the first wafer 30W. Subsequently, by sputtering or vacuum evaporation, a chromium layer and a gold layer are formed in this order on the mounting surface M1 and at the through hole BH of the first wafer 30W. As a foundation layer, the chromium layer has a thickness of, for example, 0.05 μm to 0.1 μm while the gold layer has a thickness of, for example, 0.2 μm to 1 μm.

As illustrated in FIG. 1 and FIG. 2, the mounting terminals 35a and 35b are formed on the mounting surface M1 of the first wafer 30W (the first container body 30). At the through hole BH, the side surface electrodes 37a and 37b and the connecting electrodes 38a and 38b are formed. When the mounting terminals (the hot terminals) 35a and 35b, the side surface electrodes 37a and 37b, and the connecting electrodes 38a and 38b are formed thick, electroless plating or similar method may be used to form a nickel layer and similar layer with a thickness of 1 to 3 μm on the surface of the gold layer. After step S142, the mounting terminals (the hot terminals) 35a and 35b conductively connect to the excitation electrodes 24a and 24b.

In step S143, a mounting terminal pattern for the second piezoelectric device 200 is fabricated. The B-terminal mask 40M with the patterns of the mounting terminals 45a and 45b is selected. The B-terminal mask 40M is placed on the mounting surface M1 of the first wafer 40W. Subsequently, by sputtering or vacuum evaporation, a chromium layer and a gold layer are formed in this order on the mounting surface M1 and at the through hole BH of the first wafer 40W.

As illustrated in FIG. 3, the mounting terminals 45a and 45b are formed on the mounting surface M1 of the first wafer 40W (the third container body 40). At the through hole BH, the side surface electrodes 47a and 47b and the connecting electrodes 48a and 48b are formed. When the mounting terminals (the hot terminals) 45a and 45b, the side surface electrodes 47a and 47b, and the connecting electrodes 48a and 48b are formed thick, electroless plating or similar method may be used to form a nickel layer and a similar layer with a thickness of 1 to 3 μm on the surface of the gold layer. After step S143, the mounting terminals (the hot terminals) 45a and 45b conductively connect to the excitation electrodes 24a and 24b.

In step S144, a mounting terminal pattern for the third piezoelectric device 300 is fabricated. The C-terminal mask 50M with the patterns of the mounting terminals 55a to 55c is selected. The C-terminal mask 50M is placed on the mounting surface M1 of the first wafer 50W. Subsequently, by sputtering or vacuum evaporation, a chromium layer and a gold layer are formed in this order on the mounting surface M1 and at the through hole BH of the first wafer 50W.

As illustrated in FIG. 4, the mounting terminals (the hot terminals) 55a and 55b and the mounting terminals (the grounding terminals) 55c are formed on the mounting surface M1 of the first wafer 50W (the fourth container body 50). At the through hole BH, the side surface electrodes 57a and 57b and the connecting electrodes 58a and 58b are formed. If necessary, electroless plating or similar method may be used to form a nickel layer and a similar layer on the surfaces of these terminals or electrodes. After the completion of step S144, the mounting terminals (the hot terminals) 55a and 55b conductively connect to the excitation electrodes 24a and 24b.

Subsequently, in step S145, the quartz-crystal wafer 20W, the first wafer (30W, 40W, or 50W), and the second wafer 10W in a bonded state are diced into individual piezoelectric devices. Specifically, the wafers are diced into individual first piezoelectric devices 100, second piezoelectric devices 200, or third piezoelectric devices 300 along scribe lines SL illustrated by respective one dot chain lines in FIG. 6 to FIG. 9. The dicing process employs a dicing unit with a laser beam, a dicing unit with a dicing saw, or similar dicing unit. The above-described method fabricates several hundreds to several thousands of the first piezoelectric devices 100, the second piezoelectric devices 200, or the third piezoelectric devices 300.

The piezoelectric devices with the same frequency characteristic may have varied positions (foot patterns) of the mounting terminals depending on usage or similar parameter. However, fabrications of the second wafer 10W, the first wafer (30W, 40W, or 50W), the quartz-crystal wafer 20W, and similar member with varied shapes or varied electrodes due to difference in the mounting terminals increase cost. In this embodiment, simply selecting the A-terminal mask 30M, the B-terminal mask 40M, and the C-terminal mask 50M allows fabricating the first piezoelectric device 100, the second piezoelectric device 200, or the third piezoelectric device 300.

In step S131 of the flowchart in FIG. 5, the second wafer 10W, the first wafer 30W, and the quartz-crystal wafer 20W are bonded. However, as illustrated by a dotted arrow in FIG. 5, the second wafer 10W may be bonded after steps S142 to S144. Specifically, in step S131, two wafers of the first wafer 30W and the quartz-crystal wafer 20W are bonded in the atmosphere. Subsequently, after steps S142 to S144, the two wafers, which are bonded, are bonded to the second wafer 10W under inert gas or vacuum.

Representative embodiments are described in detail above; however, as will be evident to those skilled in the relevant art, this disclosure may be changed or modified in various ways within its technical scope.

For example, while this embodiment employs the AT-cut crystal resonator, this disclosure is applicable to a tuning-fork type vibration element with a pair of vibrating arms. While the embodiment employs the crystal resonator, the embodiment may employ not only quartz-crystal material but also piezoelectric material such as lithium tantalite, lithium niobate. Further, this disclosure is applicable to a piezoelectric oscillator where an IC including an oscillating circuit is arranged inside the package as a piezoelectric device.

The method for fabricating the piezoelectric device according to a second aspect further includes preparing a second wafer. The second wafer includes a plurality of second container bodies made of insulating material. The second container body includes a second bonding surface and a ceiling surface. The second bonding surface is bonded to another principal surface of the piezoelectric vibration element. The ceiling surface is on an opposite side of the second bonding surface. The wafer bonding bonds the piezoelectric wafer, the first wafer, and the second wafer. In the method for fabricating the piezoelectric device according to a third aspect, the second container body is formed in a flat rectangular shape.

In the method for fabricating the piezoelectric device according to a fourth aspect, the piezoelectric vibration element is formed in a rectangular shape. The piezoelectric vibration element includes a connecting portion between the piezoelectric piece and a short side of the outer frame. The pair of the extraction electrodes each extend to a corresponding opposite short side via the connecting portion. The first container body is formed in a flat rectangular shape. The adjacent first container bodies include at least one common side with one through hole. The through hole is connected to the hot terminal. The pair of the extraction electrodes is connected to the respective corresponding hot terminal.

In the method for fabricating the piezoelectric device according to a fifth aspect, the first terminal mask has an opening pattern for the hot terminal. The opening pattern extends in a longitudinal direction of the first container body. In the method for fabricating the piezoelectric device according to a sixth aspect, the second terminal mask has an opening pattern for the hot terminal. The opening pattern is in a square shape. A piezoelectric device according to a seventh aspect is the piezoelectric device fabricated by the fabrication method according to the first aspect to the sixth aspect.

This disclosure provides a method for fabricating various mounting terminals without designing a piezoelectric vibration element suitable for a base portion and a similar member in each case corresponding to positions (foot patterns) of the various mounting terminals. This disclosure also provides a piezoelectric device fabricated by this fabrication method.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A method for fabricating a piezoelectric device, comprising:
preparing a piezoelectric wafer that includes a plurality of piezoelectric vibration elements, the piezoelectric vibration element including a piezoelectric piece and an outer frame, the piezoelectric piece including a pair of excitation electrodes, the outer frame surrounding the piezoelectric piece, the outer frame including a pair of extraction electrodes, the extraction electrodes being extracted from the excitation electrodes;
preparing a first wafer made of insulating material that includes a plurality of first container bodies and a plurality of through holes, the first container body including a first bonding surface to be bonded to one principal surface of the piezoelectric vibration element and a bottom surface at an opposite side of the first bonding surface, the plurality of through holes being at a common side shared by the adjacent first container bodies, the through hole passing through the adjacent first container bodies from the first bonding surface to the bottom surface;
bonding the piezoelectric wafer and the first wafer;
preparing a first terminal mask and a second terminal mask, the first terminal mask being for forming a pair of hot terminals on the bottom surface, the hot terminals including a power supply terminal and an output terminal for vibration frequency, the second terminal mask being for forming the pair of hot terminals and a grounding terminal as a ground point;
selecting an arrangement of the first terminal mask and an arrangement of the second terminal mask on the bottom surface of the first wafer, after the wafer bonding; and
forming a bottom surface with the power supply terminal and the output terminal through the first terminal mask, or a bottom surface with the power supply terminal, the output terminal, and the grounding terminal through the second terminal mask, after selecting the arrangement.

2. The method for fabricating the piezoelectric device according to claim 1, further comprising:
preparing a second wafer made of insulating material that includes a plurality of second container bodies, the second container body including a second bonding surface to be bonded to another principal surface of the piezoelectric vibration element and a ceiling surface at an opposite side of the second bonding surface, wherein
the wafer bonding bonds the piezoelectric wafer, the first wafer, and the second wafer.

3. The method for fabricating the piezoelectric device according to claim 2, wherein
the second container body is formed in a flat rectangular shape.

4. The method for fabricating the piezoelectric device according to claim 1, wherein
the piezoelectric vibration element is formed in a rectangular shape, the piezoelectric vibration element including a connecting portion between the piezoelectric piece and a short side of the outer frame, the pair of the extraction electrodes each extending to a corresponding opposite short side via the connecting portion,
the first container body is formed in a flat rectangular shape, the adjacent first container bodies including at least one common side with one through hole, the through hole being connected to the hot terminal, and
the pair of the extraction electrodes is connected to the respective corresponding hot terminal.

5. The method for fabricating the piezoelectric device according to claim 4, wherein
the first terminal mask has an opening pattern for the hot terminal, the opening pattern extending in a longitudinal direction of the first container body.

6. The method for fabricating the piezoelectric device according to claim 4, wherein
the second terminal mask has an opening pattern for the hot terminal, the opening pattern being in a square shape.

7. A piezoelectric device with the piezoelectric vibration element, wherein
the piezoelectric device is fabricated by the fabrication method according to claim 1.
